(19) United States
(12) Patent Application Publication
(10) Pub. No.: US 2013/0181270 A1
(43) Pub. Date: Jul. 18, 2013

(54) SEMICONDUCTOR DEVICE AND METHOD FOR MANUFACTURING SEMICONDUCTOR DEVICE

(71) Applicant: FUJITSU LIMITED, Kawasaki-shi (JP)

(72) Inventors: Takeshi ISHITSUKA, Isehara (JP); Hiroko TASHIRO, Ashigarakami (JP)

(73) Assignee: FUJITSU LIMITED, Kawasaki-shi (JP)

(21) Appl. No.: 13/688,602

(22) Filed: Nov. 29, 2012

(30) Foreign Application Priority Data
Jan. 18, 2012 (JP) 2012-007844

(51) Int. Cl. H01L 27/06

(52) U.S. Cl. CPC H01L 27/0629; H01L 28/40
USPC 257/296; 438/381

(57) ABSTRACT

A semiconductor device includes a capacitor, the capacitor includes: a first semiconductor region of a first conductivity type; a second semiconductor region of the first conductivity type disposed on the first semiconductor region, the second semiconductor region having a higher first-conductivity-type impurity concentration than the first semiconductor region; a third semiconductor region of the first conductivity type disposed on the second semiconductor region, the third semiconductor region including a contact region and having a higher first-conductivity-type impurity concentration than the second semiconductor region; a dielectric film disposed on the third semiconductor region; and an upper electrode disposed on the dielectric film beside the contact region.

### CROSS-REFERENCE TO RELATED APPLICATION

This application is based upon and claims the benefit of priority of the prior Japanese Patent Application No. 2012-7844, filed on Jan. 18, 2012, the entire contents of which are incorporated herein by reference.

### FIELD

The embodiments discussed herein are related to semiconductor devices.

### BACKGROUND

A logic circuit or complementary metal-oxide-semiconductor (CMOS) circuit in a semiconductor device is coupled to a pair of power supply lines for supplying direct-current (DC) power. A decoupling capacitor, called a bypass capacitor, is coupled in parallel to the pair of power supply lines to reduce voltage fluctuations in the DC power supplied to the pair of power supply lines.

The related art is disclosed in Japanese Laid-open Patent Publication Nos. 2007-157892 and 2003-347419.

### SUMMARY

According to one aspect of the embodiments, a semiconductor device includes a capacitor, the capacitor includes: a first semiconductor region of a first conductivity type; a second semiconductor region of the first conductivity type disposed on the first semiconductor region, the second semiconductor region having a higher first-conductivity-type impurity concentration than the first semiconductor region; a third semiconductor region of the first conductivity type disposed on the second semiconductor region, the third semiconductor region including a contact region and having a higher first-conductivity-type impurity concentration than the second semiconductor region; a dielectric film disposed on the third semiconductor region; and an upper electrode disposed on the dielectric film beside the contact region.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B illustrate an exemplary semiconductor device;

FIG. 2 illustrates an exemplary equivalent circuit;

FIG. 3 illustrates an exemplary capacitance;

FIG. 4 illustrates an exemplary capacitance;

FIG. 5 illustrates an exemplary capacitor;

FIG. 6 illustrates an exemplary impurity distribution of a semiconductor layer;

FIGS. 7A and 7B illustrate an exemplary semiconductor device;

FIG. 8 illustrates an exemplary capacitance;

FIG. 9 illustrates an exemplary capacitance; and

FIG. 10 illustrates an exemplary capacitor.

### DESCRIPTION OF EMBODIMENTS

A decoupling capacitor has a CMOS structure. For example, an insulating film is formed on n-type impurity regions in an upper portion of a p-type well in a silicon substrate. An upper electrode is formed on the insulating film. N-type impurity regions are formed beside the upper electrode. The n-type impurity regions below the upper electrode and the n-type impurity regions beside the upper electrode may have substantially equal impurity concentrations.

The upper electrode is formed of a polysilicon film. The polysilicon film is doped with an impurity of the same conductivity type as the n-type impurity regions therebelow, for example, an n-type impurity. Thus, a capacitor with superior frequency response is formed. One of the n-type and the p-type may be a first conductivity type, whereas the other may be a second conductivity type.

A silicon-on-insulator (SOI) substrate on which a p-type silicon layer with uniform impurity concentration is formed on the insulating layer may be used. In the capacitor, for example, the upper portion of the p-type silicon layer is qdoped with a p-type impurity, and an insulating film and an upper electrode are formed thereon in the above order.

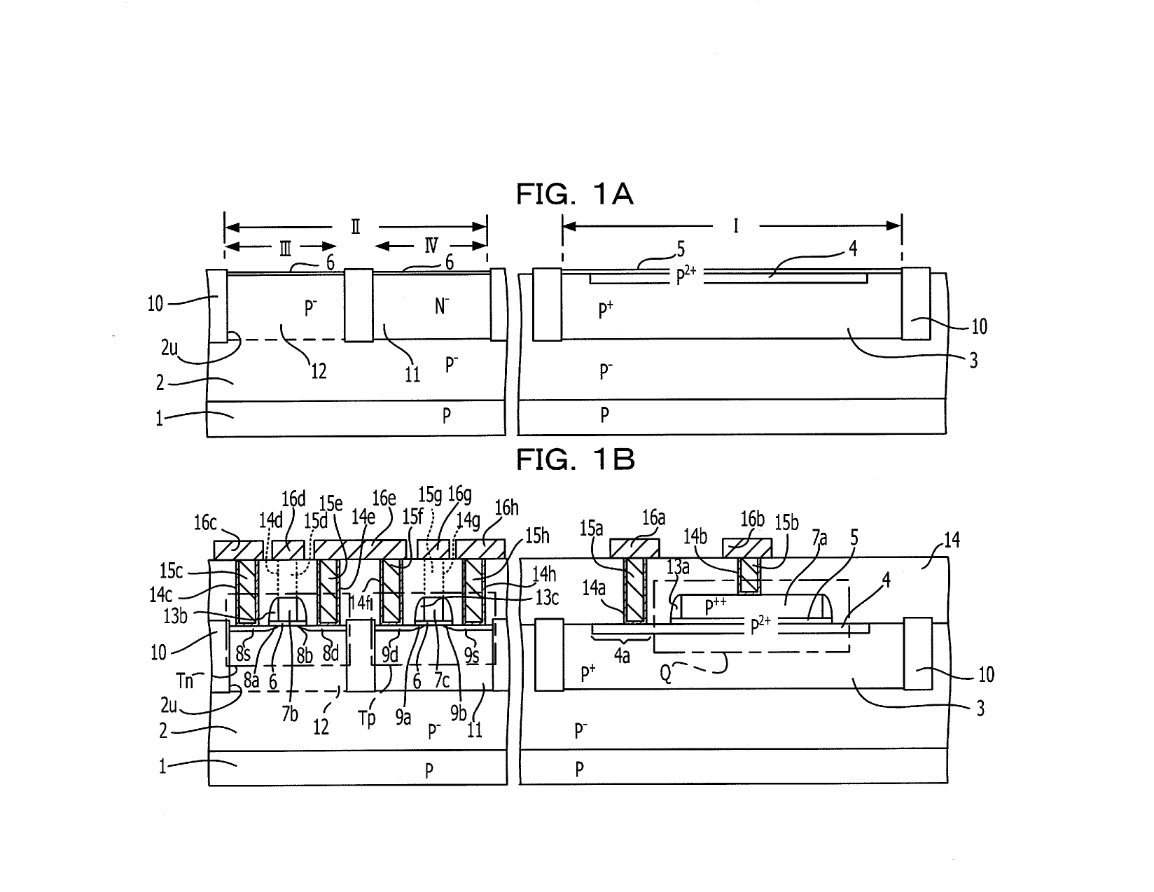

FIGS. 1A and 1B illustrate an exemplary semiconductor device.

As illustrated in FIG. 1A, a p-type silicon layer 2 having a thickness of about 1.52 μm is formed on a p-type silicon substrate 1. The p-type silicon substrate 1 contains a p-type impurity, for example, boron (B), in a concentration of about 1.3×10¹⁵ cm⁻³ and has a resistivity of about 10 Ωcm. The silicon layer 2 may contain a p-type impurity, for example, boron, in a higher concentration than the p-type silicon substrate 1, for example, about 1×10¹⁶ cm⁻³.

The silicon layer 2 may be a p-type semiconductor region epitaxially grown on the p-type silicon substrate 1 and having a substantially uniform impurity concentration distribution. Alternatively, the silicon layer 2 may be a p-type semiconductor region formed in the silicon substrate 1 by ion implantation of a p-type impurity, for example, boron.

A silicon oxide film (not illustrated) and a silicon nitride film (not illustrated) are formed on the silicon layer 2 in the above order. Openings are then formed in isolation regions by photolithography and etching. These films may be used as a hard mask (not illustrated). Isolation trenches 2u are formed in the p-type silicon layer 2 through the openings in the hard mask.

A silicon oxide film, which is an insulating film, is deposited in the isolation trenches 2u by chemical vapor deposition (CVD). The silicon oxide film is removed from the hard mask by chemical mechanical polishing (CMP), and the hard mask is removed. The silicon oxide films remaining in the isolation trenches 2u are used as shallow trench isolations (STIs) 10. The STIs 10 may be among isolation insulators. Instead of the STIs 10, isolation insulators may be formed by local oxidation of silicon (LOCOS).

A capacitor-forming region I defined by the STIs 10 in the silicon layer 2 is doped with a p-type impurity, for example, boron, by ion implantation. Thus, a first p-type impurity diffusion region 3 may be formed to a depth of, for example, about 0.52 μm from the surface of the p-type silicon layer 2. The first p-type impurity diffusion region 3 may have a higher p-type impurity concentration than the p-type silicon layer 2, for example, from 5×10¹⁸ to 5×10¹⁹ cm⁻³. For ion implantation of a p-type impurity, the region other than the capacitor-forming region I may be covered with, for example, a photoresist (not illustrated).

The first p-type impurity diffusion region 3 is doped with a p-type impurity, for example, boron, by ion implantation. Thus, a second p-type impurity diffusion region 4 is formed to a depth of, for example, about 20 nm from the surface of the first p-type impurity diffusion region 3. The second p-type impurity diffusion region 4 has a higher p-type impurity concentration than the first p-type impurity diffusion region 3, for example, from 1×10¹⁹ to 5×10²⁰ cm⁻³. Accordingly, the first p-type impurity diffusion region 3 below the second p-type impurity diffusion region 4 becomes thinner. The second p-type impurity diffusion region 4 may be, for example, wider than an upper electrode 7a. For ion implantation of a p-type impurity, the region other than the region where the second p-type impurity diffusion region 4 is to be formed is covered with, for example, a photoresist (not illustrated).

A first ion acceleration energy for forming the first p-type impurity diffusion region 3 may be higher than a second ion acceleration energy for forming the second p-type impurity diffusion region 4. For example, the first ion acceleration energy may be from 50 to 100 keV, whereas the second ion acceleration energy may be from 1 to 5 keV.

A dielectric film 5 is formed on the surface of the second p-type impurity diffusion region 4. The dielectric film 5 may be, for example, a silicon oxide film having a thickness of about 2 nm. The dielectric film 5 may be formed by, for example, thermal oxidation of the surface of the silicon layer 2, the first p-type impurity diffusion region 3, and the second p-type impurity diffusion region 4.

In a CMOS-forming region II, an n-type MOS-transistor forming region III and a p-type MOS-transistor forming region IV are defined by the STIs 10. Before the formation of the dielectric film 5, an n-well 11 is formed in the p-type MOS-transistor forming region IV by ion implantation of an n-type impurity. The n-well 11 may have an n-type impurity concentration of, for example, about 2×10¹⁶ cm⁻³. For ion implantation of an n-type impurity, the region other than the p-type MOS-transistor forming region IV is covered with a photoresist (not illustrated). The portion of the p-type silicon layer 2 in the n-type MOS-transistor forming region III may be used as a p-well 12. The p-type impurity concentration of the p-well 12 may be increased by ion implantation of a p-type impurity into the portion of the p-type silicon layer 2 in the n-type MOS-transistor forming region III. The difference in p-type impurity concentration between the p-well 12 and the p-type silicon layer 2 may be within one order of magnitude.

In the CMOS-forming region II, gate insulators 6 are formed on the surface of the silicon layer 2. The gate insulators 6 are formed by, for example, thermal oxidation of the surface of the p-type silicon layer 2. If the gate insulators 6 and the dielectric film 5 are designed to have substantially the same thickness, they may be formed substantially contemporaneously.

If the gate insulators 6 and the dielectric film 5 are designed to have different thicknesses, for example, a silicon oxide film may be formed by thermal oxidation in both of the capacitor-forming region I and the CMOS-forming region II so that the silicon oxide film has a thickness which is substantially the same thickness as the thinner one of the gate insulators 6 and the dielectric film 5. After the region corresponding to the thinner one of the gate insulators 6 and the dielectric film 5 is covered with a resist, further thermal oxidation may be performed on the other region to increase the thickness of the silicon oxide film.

As illustrated in FIG. 1B, a polysilicon film is formed on the dielectric film 5 and the gate insulators 6 by CVD and is then patterned by photolithography and etching. An upper electrode 7a including the patterned polysilicon film is formed on the capacitor-forming region I in the silicon layer 2. A first gate electrode 7b and a second gate electrode 7c that include the patterned polysilocon filim are formed on the p-type MOS-transistor forming region IV and the n-type MOS-transistor forming region III, respectively.

In the capacitor-forming region I, the upper electrode 7a, the dielectric film 5 therebelow, and the second p-type impurity diffusion region 4 form a capacitor Q. The first p-type impurity diffusion region 3 and the second p-type impurity diffusion region 4 may function as the lower electrode of the capacitor Q. A portion of the second p-type impurity diffusion region 4 extending beside the upper electrode 7a may correspond to a contact region 4a. The capacitor Q may be used as, for example, a decoupling capacitor. Extension regions 8a, 8b, 9a, and 9b for the MOS transistors may then be formed in the silicon layer 2.

A resist pattern (not illustrated) is formed on the silicon layer 2 so as to cover the p-type MOS-transistor forming region IV and the capacitor-forming region I and expose the n-type MOS-transistor forming region III. The p-well 12 is doped with an n-type impurity, for example, phosphorus (P), by ion implantation to form n-type extension regions 8a and 8b on either side of the first gate electrode 7b. The n-type extension regions 8a and 8b may have an n-type impurity concentration of, for example, about 5×10¹⁸ cm⁻³. The resist pattern (not illustrated) is then removed.

A resist pattern (not illustrated) is formed on the silicon layer 2 so as to cover the n-type MOS-transistor forming region III and the capacitor-forming region I and expose the p-type MOS-transistor forming region IV. The n-well 11 is doped with a p-type impurity, for example, boron, by ion implantation to form p-type extension regions 9a and 9b on either side of the second gate electrode 7c. The p-type extension regions 9a and 9b may have a p-type impurity concentration of, for example, about 5×10¹⁸ cm⁻³. The resist pattern (not illustrated) is then removed.

An insulating film, for example, a silicon oxide film, is formed on the silicon layer 2, the gate electrodes 7b and 7c, and the upper electrode 7a by CVD and is then etched back. The silicon oxide films remaining on the sides of the first gate electrode 7b, the second gate electrode 7c, and the upper electrode 7a are used as insulating sidewalls 13a, 13b, and 13c. Source regions 8s and 9s and drain regions 8d and 9d for the MOS transistors are then formed.

A resist pattern (not illustrated) is formed on the silicon layer 2 so as to cover the p-type MOS-transistor forming region IV and the capacitor-forming region I and expose the n-type MOS-transistor forming region III. Using the first gate electrode 7b and the surrounding sidewalls 13b as a mask, the p-well 12 is doped with an n-type impurity by ion implantation to form an n-type source/drain region 8s and 8d. The n-type source/drain region 8s and 8d may have an n-type impurity concentration of, for example, about 1×10²⁰ cm⁻³. The polysilicon film corresponding to the first gate electrode 7b is doped with an n-type impurity by ion implantation. The polysilicon film may have an n-type impurity concentration of about 1×10²⁰ cm⁻³.

The resist pattern (not illustrated) is then removed from the silicon layer 2. The first gate electrode 7b, the gate insulator 6, the n-type source/drain region 8s and 8d, and the p-well 12 form an n-type MOS transistor Tn.

A resist pattern (not illustrated) is formed on the silicon layer 2 so as to cover the n-type MOS-transistor forming region III and expose the silicon layer 2 in the p-type MOS-transistor forming region IV and the upper electrode 7a in the capacitor-forming region I. Using the second gate electrode 7c and the surrounding sidewalls 13c as a mask, the n-well 11 is doped with a p-type impurity by ion implantation to form a p-type source/drain region 9s and 9d in the n-well 11. The p-type source/drain region 9s and 9d may have a p-type impurity concentration of, for example, about 1×10²⁰ cm⁻³.

The polysilicon films corresponding to the second gate electrode 7c and the upper electrode 7a are doped with a p-type impurity by ion implantation. The polysilicon films may have a p-type impurity concentration of about 1×10²⁰ cm⁻³. The upper electrode 7a has a higher p-type impurity concentration than the second p-type impurity diffusion region 4 therebelow. The impurity concentration of the contact region 4a of the second p-type impurity diffusion region 4 may be increased by ion implantation of a p-type impurity.

The resist pattern (not illustrated) is then removed from the silicon layer 2. The second gate electrode 7c, the gate insulator 6, the p-type source region 9s, the p-type drain region 9d, and the n-well 11 form a p-type MOS transistor Tp.

An interlayer insulator 14 is formed on the silicon layer 2 so as to cover the p-type MOS transistor Tp, the n-type MOS transistor Tn, and the capacitor Q. The upper surface of the interlayer insulator 14 is planarized by CMP. The interlayer insulator 14 is patterned by photolithography and etching. Thus, contact holes 14a to 14h are formed above the contact region 4a of the second p-type impurity diffusion region 4, the upper electrode 7a, the n-type source region 8s, the first gate electrode 7b, the n-type drain region 8d, the p-type drain region 9d, the second gate electrode 7c, and the p-type source region 9s, respectively. Conductive plugs 15a to 15h are then formed in the contact holes 14a to 14h, respectively. A conductive film is formed on the interlayer insulator 14 and is patterned to form wiring lines 16a to 16e, 16g, and 16h.

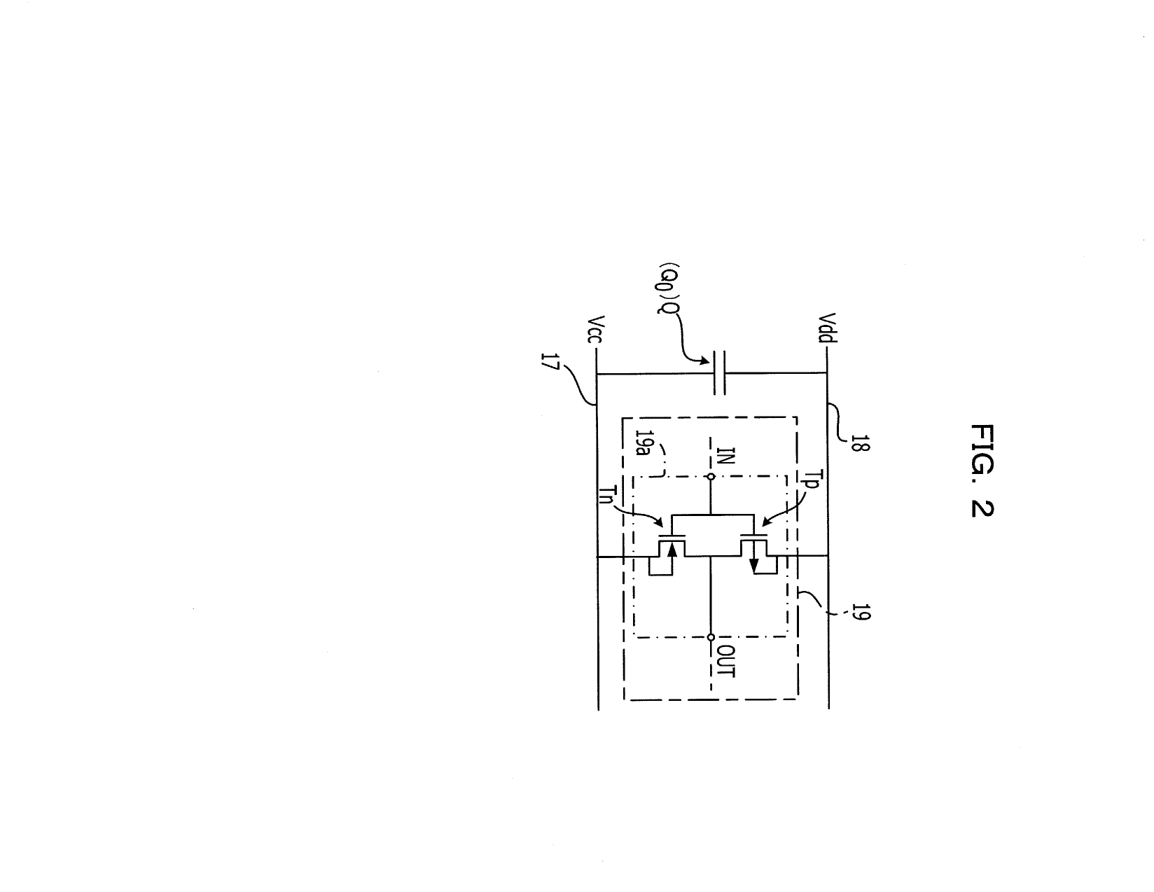

FIG. 2 illustrates an exemplary equivalent circuit. The equivalent circuit illustrated in FIG. 2 may be the equivalent circuit of the semiconductor device illustrated in FIG. 1B. As illustrated in FIG. 2, the wiring lines 16a to 16e, 16g, and 16h electrically coupled to the p-type MOS transistor Tp, the n-type MOS transistor Tn, and the capacitor Q via the conductive plugs 15a to 15h are coupled to a pair of first and second power supply lines 17 and 18. The p-type MOS transistor Tp, the n-type MOS transistor Tn, and the wiring lines 16c to 16e, 16g, and 16h coupled thereto via the conductive plugs 15a to 15h may form a CMOS 19a included in a logic circuit 19.

A voltage Vdd is applied to the second power supply line 18, whereas a voltage Vcc, for example, a ground voltage, is applied to the first power supply line 17. The second power supply line 18 is coupled to the contact region 4a of the second p-type impurity diffusion region 4 via the wiring line 16a and the conductive plug 15a. The first power supply line 17 is coupled to the upper electrode 7a via the wiring line 16b and the conductive plug 15b. The p-type silicon layer 2 may be set to substantially the same potential as the second p-type impurity diffusion region 4.

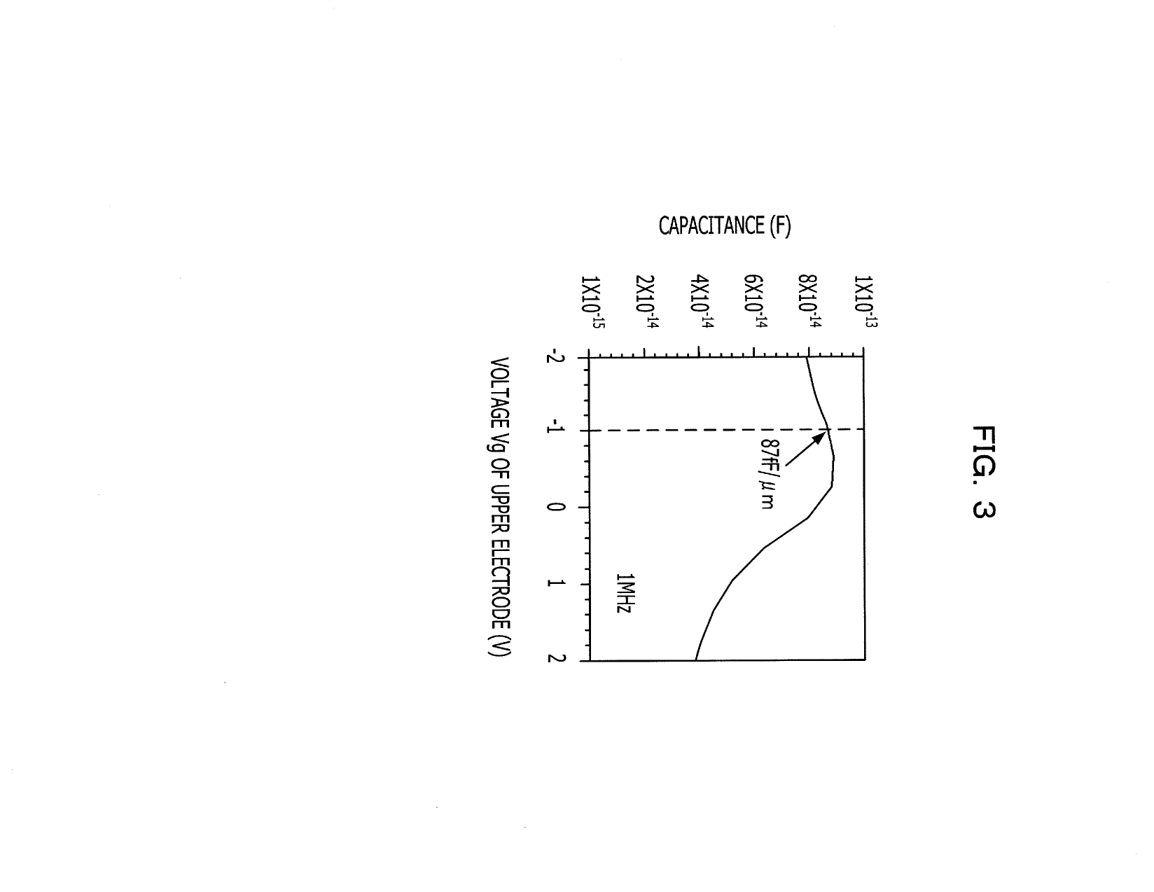

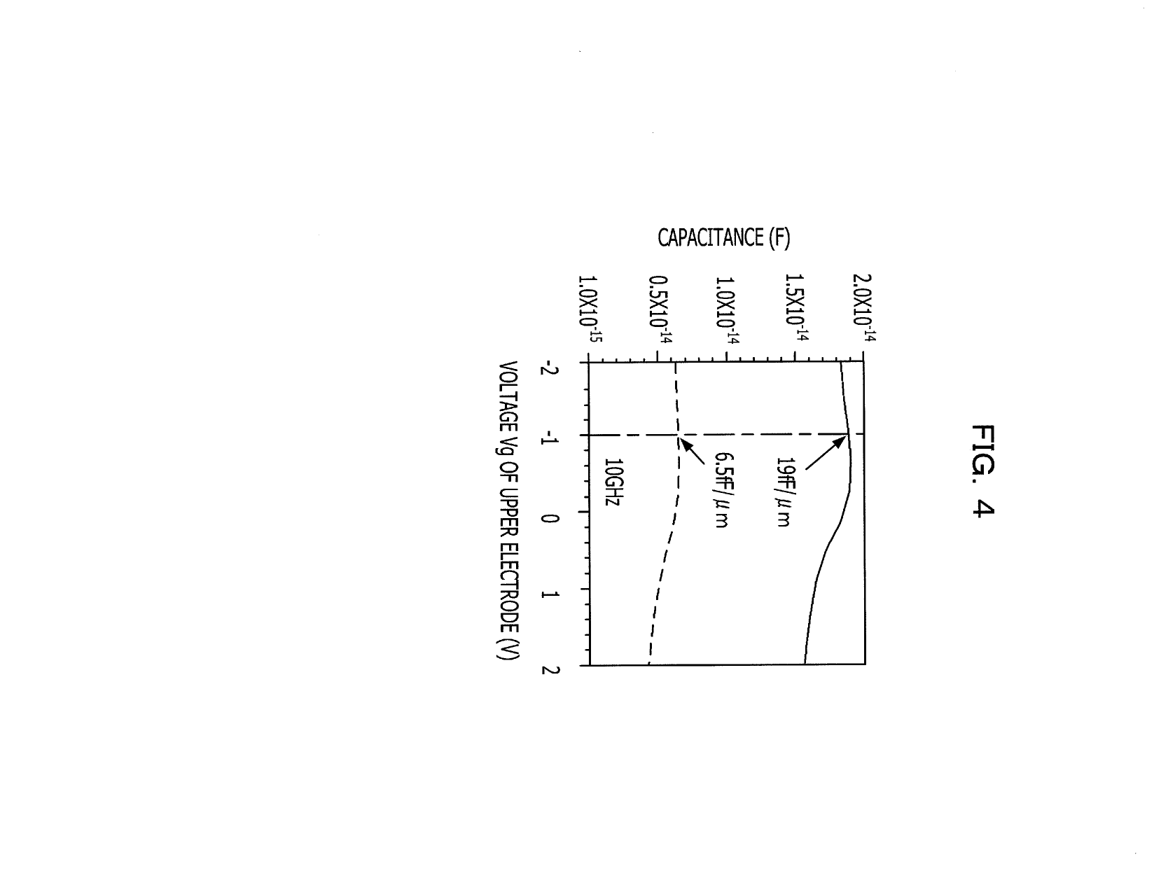

In the capacitor Q, for example, the potential difference of the upper electrode 7a with respect to the second p-type impurity diffusion region 4 is set to Vg, and the frequency of signals applied to an input terminal IN of the CMOS 19a is set to 1 MHz or 10 GHz. FIGS. 3 and 4 illustrate an exemplary capacitance. The solid lines in FIGS. 3 and 4 indicate changes in the capacitance of the capacitor Q illustrated in FIG. 1B with the potential difference Vg. FIGS. 3 and 4 may illustrate the results of analysis using Sentaurus Device, which is a device simulator available from Synopsys, Inc. The capacitance at a potential difference Vg of −1 V may be 87 fF/μm at a frequency of 1 MHz and may be 19 fF/μm at a frequency of 10 GHz. A potential difference Vg of −1 V indicates that a voltage of +1 V is applied to the second p-type impurity diffusion region 4 with respect to the upper electrode 7a.

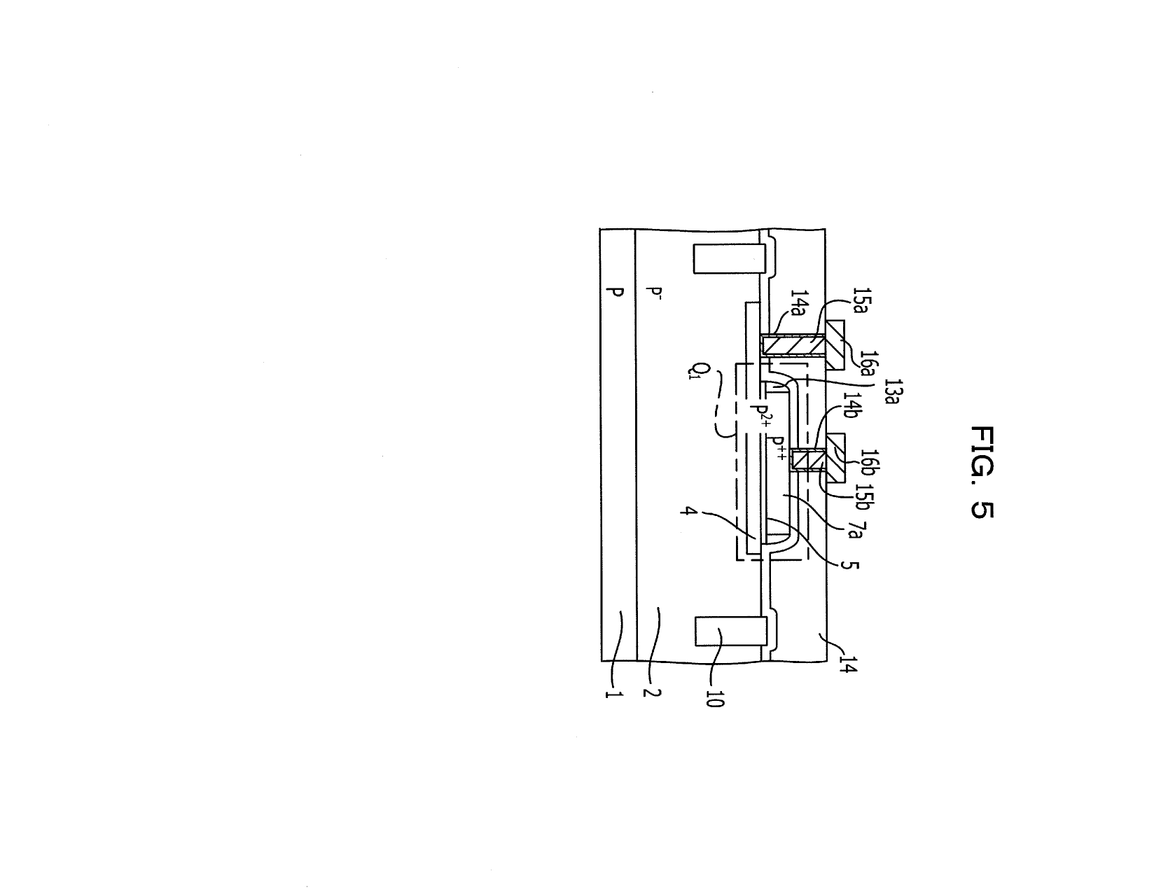

FIG. 5 illustrates an exemplary a capacitor. FIG. 5 illustrates a capacitor Q₁ having a MOS structure.

The capacitor Q₁ illustrated in FIG. 5 is similar to the capacitor Q illustrated in FIG. 1B except that the first p-type impurity diffusion region 3 is omitted. The elements illustrated in FIG. 5 that are substantially the same as or similar to the elements illustrated in FIG. 1B may be indicated by the same designations, and a description thereof may be omitted or reduced. The elements illustrated in FIG. 5 may have substantially the same impurity concentrations as the elements illustrated in FIG. 1B.

For example, the capacitor Q₁ illustrated in FIG. 5 is coupled to the power supply lines 17 and 18 illustrated in FIG. 2. The potential difference of the upper electrode 7a with respect to the second p-type impurity diffusion region 4 is set to Vg, and the operating frequency of the logic circuit 19 illustrated in FIG. 2 is set to 10 GHz. The dashed line in FIG. 4 indicates changes in the capacitance of the capacitor Q₁ illustrated in FIG. 5 with the potential difference Vg. The capacitance at a potential difference Vg of −1 V is 6.5 fF/μm. The capacitance of the capacitor Q illustrated in FIG. 1B at a frequency of 10 GHz may be about 2.9 times the capacitance of the capacitor Q₁ illustrated in FIG. 5.

The capacitor Q. illustrated in FIG. 5 and the capacitor Q illustrated in FIG. 1B may have the relationship indicated by the solid line in FIG. 3 between the voltage of the upper electrode 7a and the capacitance when the frequency of signals applied to the logic circuit 19 is 1 MHz.

The capacitor Q illustrated in FIG. 1B and the capacitor Q₁ illustrated in FIG. 5 differ in the presence or absence of the first p-type impurity diffusion region 3 between the p-type silicon layer 2 and the second p-type impurity diffusion region 4.

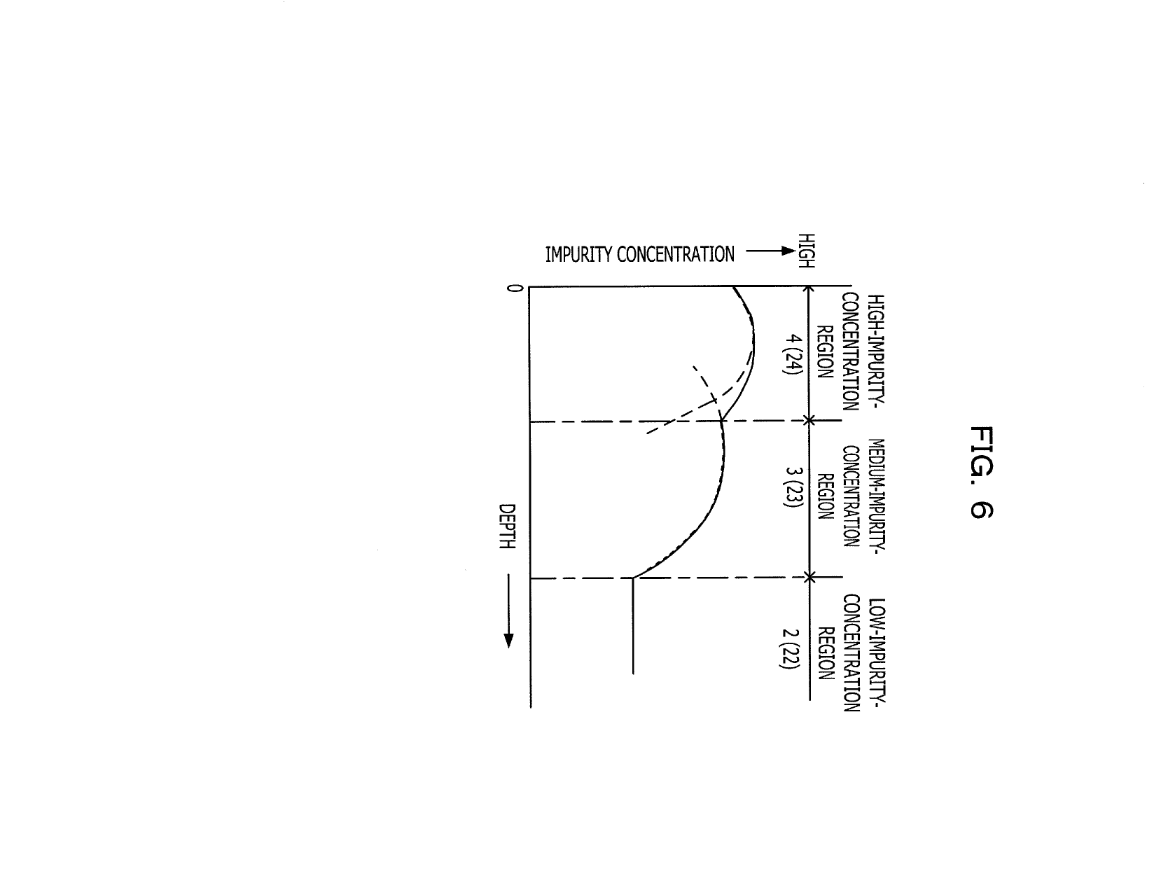

FIG. 6 illustrates an exemplary impurity distribution of a semiconductor layer. FIG. 6 may illustrate the impurity distribution of a semiconductor layer below a dielectric film in a capacitor. As indicated by the dashed lines in FIG. 6, the p-type impurity distributions along the depth of the first p-type impurity diffusion region 3 and the second p-type impurity diffusion region 4 formed by ion implantation are parabolic with peaks. The peak of the impurity concentration distribution of the first p-type impurity diffusion region 3 may be lower than the peak of the impurity concentration distribution of the second p-type impurity diffusion region 4.

The difference in p-type impurity concentration between the first p-type impurity diffusion region 3 and the second p-type impurity diffusion region 4 may be within one order of magnitude. The bottom of the second p-type impurity diffusion region 4 may have a higher impurity concentration by overlapping the upper portion of the first p-type impurity diffusion region 3. Accordingly, the high-concentration region of the second p-type impurity diffusion region 4 may be substantially thicker.

Because the second p-type impurity diffusion region 4 is coupled beside the upper electrode 7a to the second power supply line 18, the majority carriers in the second p-type impurity diffusion region 4, i.e., holes, travel laterally. As the high-impurity-concentration region of the second p-type impurity diffusion region 4 becomes deeper, it has a lower resistance for the travelling carriers. Accordingly, more holes travel to the region below the upper electrode 7a, so that the capacitor Q may have a higher capacitance. This results in a higher capacitance at high frequencies.

Because the capacitor Q₁ illustrated in FIG. 5 does not include the first p-type impurity diffusion region 3, the high-impurity-concentration region of the second p-type impurity diffusion region 4 may be thinner than that of the second p-type impurity diffusion region 4 illustrated in FIG. 1B. Accordingly, the lateral resistance may be higher. This may result in fewer holes supplied to the second p-type impurity diffusion region 4 and therefore a lower capacitance at high frequencies.

For example, if the voltage Vg of the upper electrode 7a in FIGS. 3 and 4 is positive with respect to the second p-type impurity diffusion region 4, the majority carriers in the second p-type impurity diffusion region 4, for example, holes, are not supplied in large quantities to the region below the upper electrode 7a. This may result in a lower capacitance.

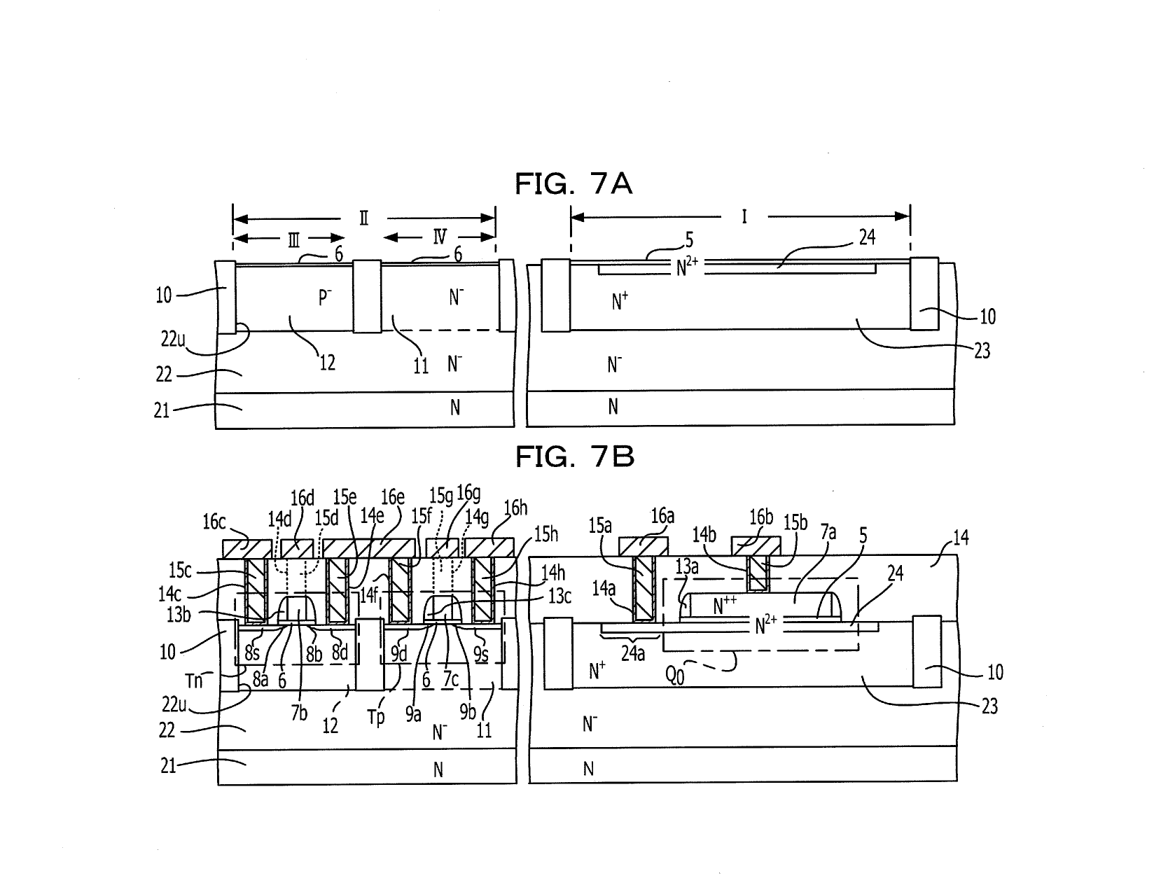

FIGS. 7A and 7B illustrate an exemplary semiconductor device. The elements illustrated in FIGS. 7A and 7B that are substantially the same as or similar to the elements illustrated in FIG. 1B may be indicated by the same designations, and a description thereof may be omitted or reduced.

As illustrated in FIG. 7A, an n-type silicon layer 22 having a thickness of about 1.52 μm is formed on an n-type silicon substrate 21. The n-type silicon substrate 21 contains an n-type impurity, for example, phosphorus, in a concentration of about 1.3×10¹⁵ cm⁻³ and has a resistivity of about 10 Ωcm. The silicon layer 22 may contain an n-type impurity, for example, phosphorus, in a concentration of, for example, about 1×10¹⁶ cm⁻³.

The silicon layer 22 may correspond to an n-type impurity region epitaxially grown on the n-type silicon substrate 21. Alternatively, the silicon layer 22 may correspond to an n-type impurity region formed in the silicon substrate 21 by ion implantation of an n-type impurity, for example, phosphorus.

Isolation insulators, for example, STIs 10, are formed in the silicon layer 22. A capacitor-forming region I in the silicon layer 22 is doped with an n-type impurity, for example, phosphorus, by ion implantation with an acceleration energy of 100 to 150 keV. Thus, a first n-type impurity diffusion region 23 is formed to a depth of, for example, about 0.52 μm from the surface of the n-type silicon layer 22. The first n-type impurity diffusion region 23 has a higher n-type impurity concentration than the n-type silicon layer 22, for example, from 5×10¹⁸ to 5×10¹⁹ cm⁻³. For ion implantation of an n-type impurity, the region other than the capacitor-forming region I is covered with, for example, a photoresist (not illustrated).

The first n-type impurity diffusion region 23 is partially doped with an n-type impurity, for example, phosphorus, by ion implantation with an acceleration energy of 5 to 10 keV. Thus, a second n-type impurity diffusion region 24 is formed to a depth of, for example, about 20 nm from the surface of the first n-type impurity diffusion region 23. The second n-type impurity diffusion region 24 has an impurity concentration of, for example, from 1×10¹⁹ to 5×10²⁰ cm⁻³. The second n-type impurity diffusion region 24 may be wider than an upper electrode 7a. Accordingly, the first n-type impurity diffusion region 23 below the second n-type impurity diffusion region 24 becomes thinner. For ion implantation of an n-type impurity, the region other than the region where the second n-type impurity diffusion region 24 is to be formed may be covered with, for example, a photoresist (not illustrated).

A dielectric film 5 is formed on the surface of the second n-type impurity diffusion region 24. The dielectric film 5 is, for example, a silicon oxide film having a thickness of 2 nm. The dielectric film 5 may be formed by, for example, thermal oxidation of the surface of the silicon layer 22, the first n-type impurity diffusion region 23, and the second n-type impurity diffusion region 24.

In a CMOS-forming region II, an n-type MOS-transistor forming region III and a p-type MOS-transistor forming region IV are defined by the STIs 10. Before the formation of the dielectric film 5, a p-well 12 is formed in the portion of the n-type silicon layer 22 in the n-type MOS-transistor forming region III by ion implantation of a p-type impurity. The p-well 12 may have a p-type impurity concentration of, for example, about 2×10¹⁶ cm⁻³. For ion implantation of a p-type impurity, the region other than the n-type MOS-transistor forming region III is covered with a photoresist (not illustrated). The portion of the n-type silicon layer 22 in the p-type MOS-transistor forming region IV may be used as an n-well 11. The n-type impurity concentration of the n-well 11 may be increased by ion implantation of an n-type impurity into the portion of the n-type silicon layer 22 in the p-type MOS-transistor forming region IV. The difference in n-type impurity concentration between the n-well 11 and the n-type silicon layer 22 may be within one order of magnitude.

Gate insulators 6 are formed on the surface of the silicon layer 22 in the CMOS-forming region II. The gate insulators 6 may be formed by, for example, thermal oxidation of the surface of the silicon layer 22. The thicknesses of the gate insulators 6 and the dielectric film 5 may be controlled as illustrated in FIG. 1A.

A polysilicon upper electrode 7a, a polysilicon first gate electrode 7b, and a polysilicon second gate electrode 7c are formed on the dielectric film 5 and the gate insulators 6 in a manner that is substantially the same as or similar to the manner illustrated in FIG. 1B.

In the capacitor-forming region I, the upper electrode 7a, the dielectric film 5 therebelow, and the second n-type impurity diffusion region 24 form a capacitor Q₀. The second n-type impurity diffusion region 24 may function as the lower electrode of the capacitor Q₀. A portion of the second n-type impurity diffusion region 24 extending beside the upper electrode 7a may correspond to a contact region 24a. The capacitor Q₀ may be used as, for example, a decoupling capacitor.

N-type extension regions 8a and 8b for the n-type MOS transistor are formed in the p-well 12 in a manner that is substantially the same as or similar to the manner illustrated in FIG. 1B. P-type extension regions 9a and 9b for the p-type MOS transistor are formed in the n-well 11. The n-type extension regions 8a and 8b may have an n-type impurity concentration of, for example, about 5×10¹⁸ cm⁻³. The p-type extension regions 9a and 9b may have a p-type impurity concentration of, for example, about 5×10¹⁸ cm⁻³.

Insulating sidewalls 13a, 13b, and 13c are formed on the sides of the first gate electrode 7b, the second gate electrode 7c, and the upper electrode 7a in a manner that is substantially the same as or similar to the manner illustrated in FIG. 1B. An n-type source region 8s and an n-type drain region 8d for the n-type MOS transistor are formed in the p-well 12 in a manner that is substantially the same as or similar to the manner illustrated in FIG. 1B. A p-type source region 9s and a p-type drain region 9d for the p-type MOS transistor are formed in the n-well 11. The n-type source region 8s and the n-type drain region 8d may have an n-type impurity concentration of, for example, about 1×10²⁰ cm⁻³. The p-type source region 9s and the p-type drain region 9d may have a p-type impurity concentration of, for example, about 1×10²⁰ cm⁻³.

The polysilicon films corresponding to the first gate electrode 7b and the upper electrode 7a are doped with an n-type impurity by ion implantation. The polysilicon films may have an n-type impurity concentration of, for example, about 1×10²⁰ cm⁻³. The upper electrode 7a may have a higher n-type impurity concentration than the second n-type impurity diffusion region 24 therebelow. When the n-type source region 8s and the n-type drain region 8d are formed, the impurity concentration of the contact region 24a of the second n-type impurity diffusion region 24 may be increased by ion implantation of an n-type impurity. The polysilicon film forming the second gate electrode 7c may have a p-type impurity concentration of, for example, about 1×10²⁰ cm⁻³.

An n-type MOS transistor Tn may include the first gate electrode 7b, the gate insulator 6, the n-type source region 8s, the n-type drain region 8d, and the p-well 12. A p-type MOS transistor Tp may include the second gate electrode 7c, the gate insulator 6, the p-type source region 9s, the p-type drain region 9d, and the n-well 11.

An interlayer insulator 14 is formed so as to cover the p-type MOS transistor Tp, the n-type MOS transistor Tn, and the capacitor Q₀ in a manner that is substantially the same as or similar to the manner illustrated in FIG. 1B. Contact holes 14a to 14h are formed in the interlayer insulator 14, and conductive plugs 15a to 15h are formed in the contact holes 14a to 14h, respectively. Wiring lines 16a to 16e, 16g, and 16h are formed on the interlayer insulator 14.

As illustrated in the equivalent circuit diagram in FIG. 2, the wiring lines 16a to 16e, 16g, and 16h electrically coupled to the p-type MOS transistor Tp, the n-type MOS transistor Tn, and the capacitor Qₒ via the conductive plugs 15a to 15h may be coupled to a pair of first and second power supply lines 17 and 18. The n-type MOS transistor Tp, the n-type MOS transistor Tn, and the wiring lines 16c to 16e, 16g, and 16h coupled thereto via the conductive plugs 15a to 15h may correspond to a CMOS 19a included in a logic circuit 19.

A voltage Vdd is applied to the second power supply line 18, whereas a voltage Vcc is applied to the first power supply line 17. The first power supply line 17 is coupled to the contact region 24a of the second n-type impurity diffusion region 24 via the wiring line 16a and the conductive plug 15a. The second power supply line 18 is coupled to the upper electrode 7a via the wiring line 16b and the conductive plug 15b. The n-type silicon layer 22 may be set to, for example, substantially the same potential as the second n-type impurity diffusion region 24.

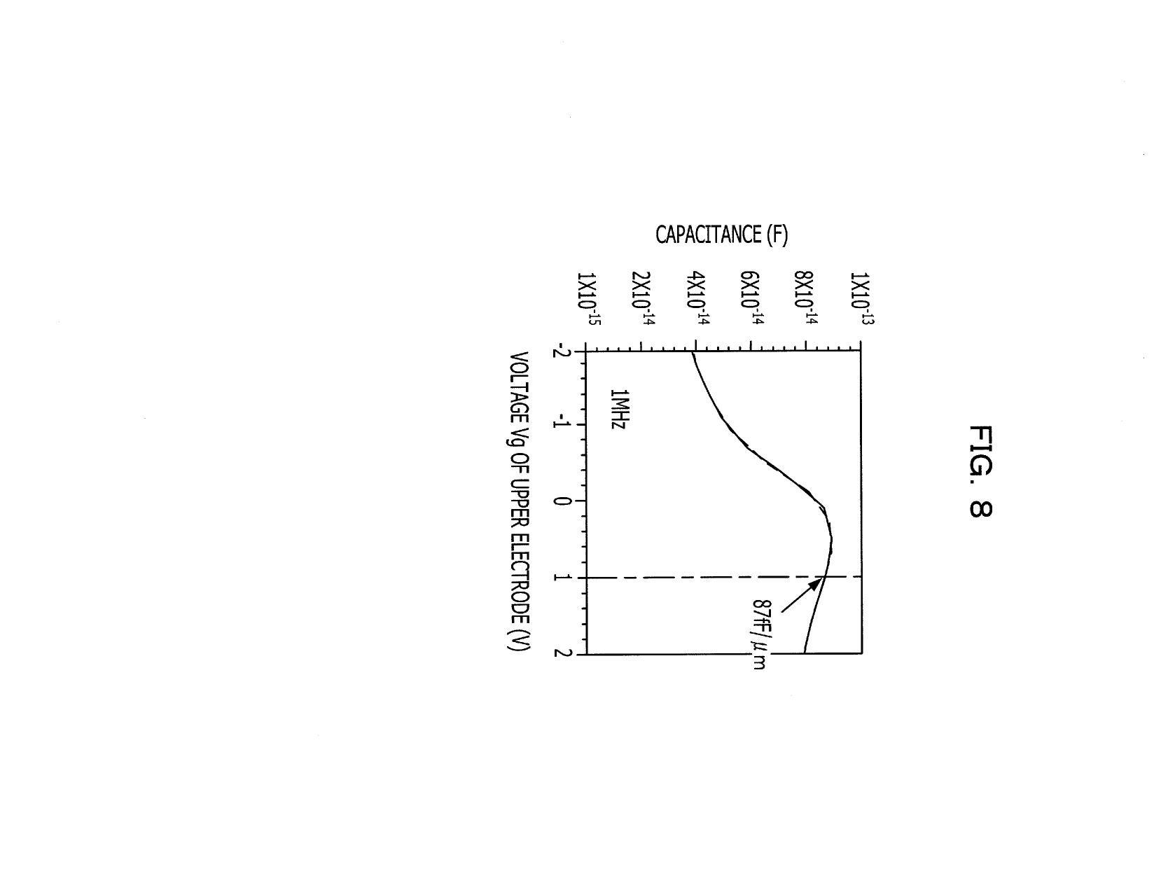

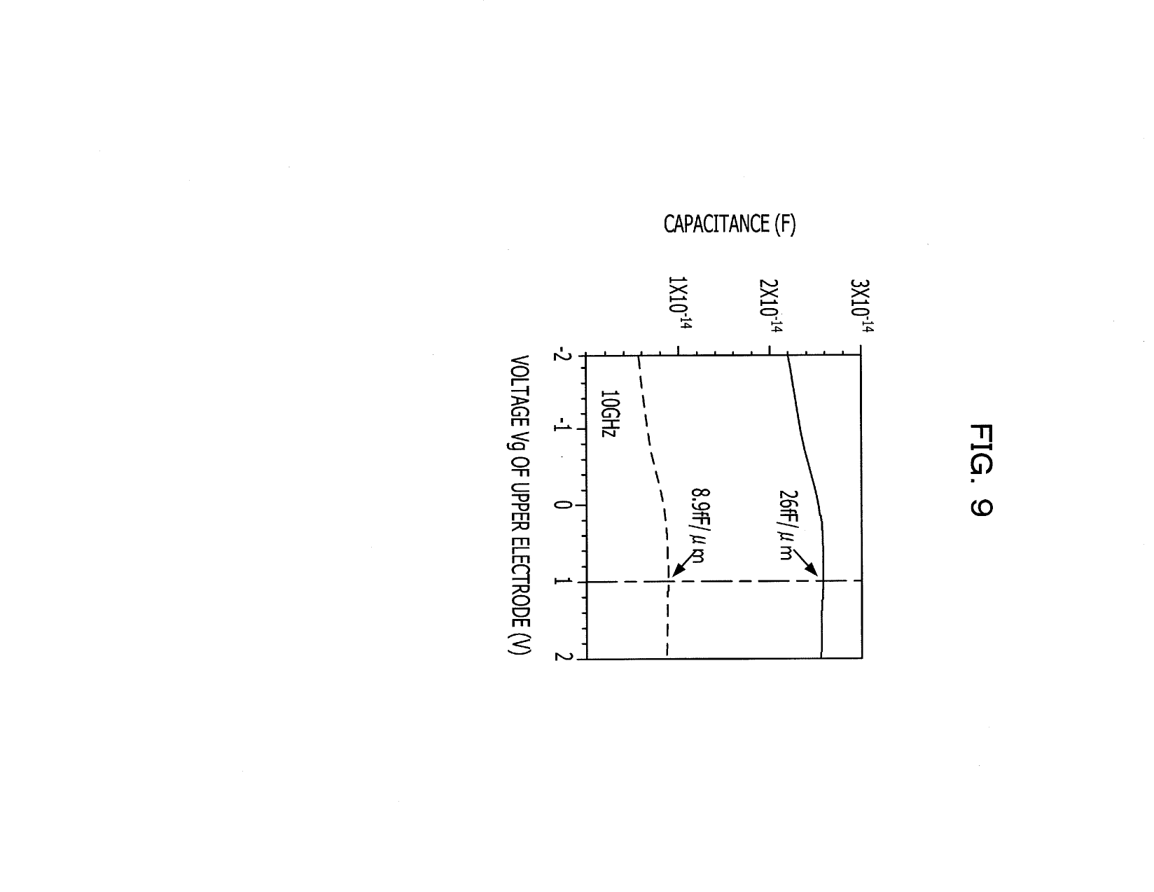

FIGS. 8 and 9 illustrate an exemplary capacitance. In the capacitor Q₀ having the above configuration, for example, the potential difference of the upper electrode 7a with respect to the second n-type impurity diffusion region 24 is set to Vg, and the frequency of signals applied to an input terminal IN of the CMOS 19a is set to 1 MHz or 10 GHz. FIGS. 8 and 9 indicate changes in the capacitance of the capacitor Q₀ with the potential difference Vg. FIGS. 8 and 9 may illustrate a results of analysis using Sentaurus Device, which is a device simulator available from Synopsys, Inc. The capacitance at a potential difference Vg of 1 V is 87 fF/μm at a frequency of 1 MHz and is 26 fF/μm at a frequency of 10 GHz.

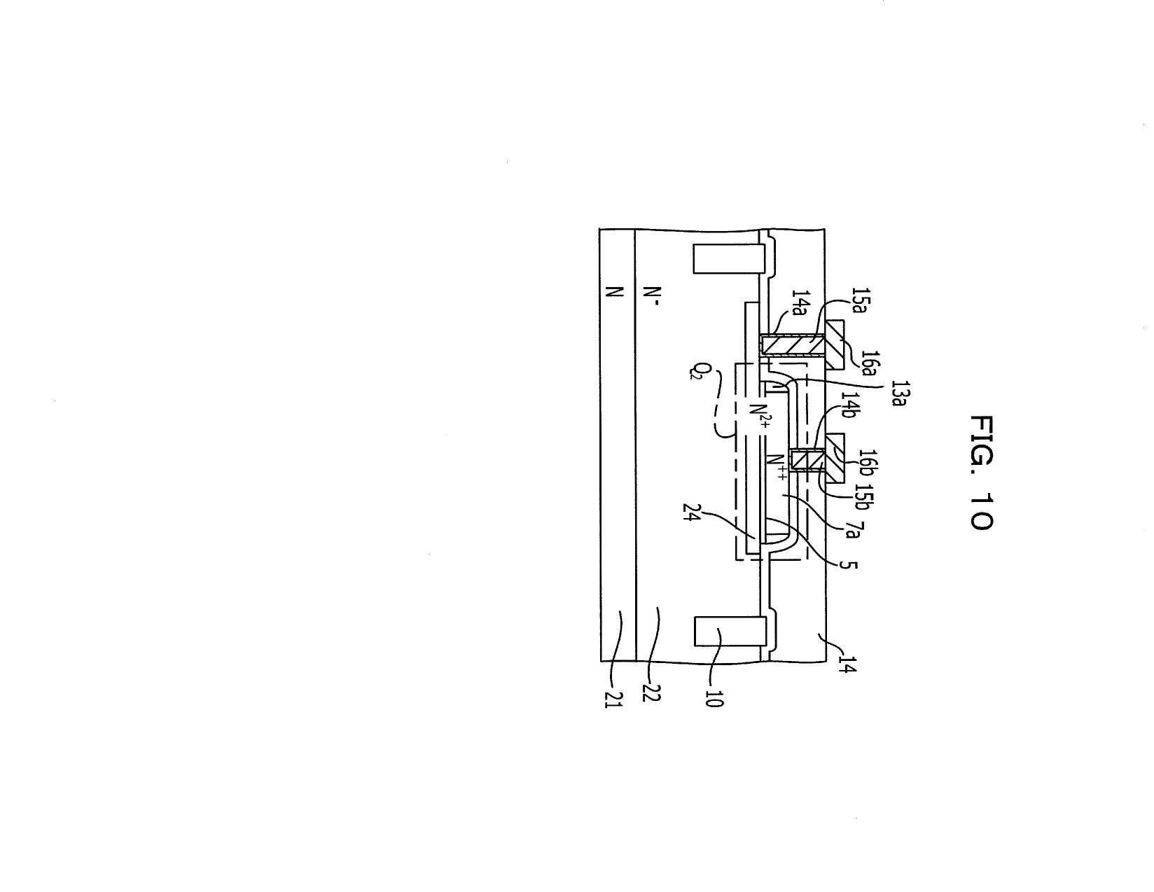

FIG. 10 illustrates an exemplary capacitor.

A capacitor Q₂ illustrated in FIG. 10 is similar to the capacitor Q₀ illustrated in FIG. 7B except that the first n-type impurity diffusion region 23 is omitted. The elements illustrated in FIG. 10 that are substantially the same as or similar to the elements illustrated in FIG. 7B may be indicated by the same designations, and a description thereof may be omitted or reduced. The elements illustrated in FIG. 10 may have substantially the same impurity concentrations as the elements illustrated in FIG. 7B.

In the capacitor Q₂ illustrated in FIG. 10, the potential difference of the upper electrode 7a with respect to the second n-type impurity diffusion region 24 may be set to Vg. The dashed lines in FIGS. 8 and 9 indicate changes in the capacitance of the capacitor Q₂ with the potential difference Vg for varying frequencies of signals applied to the input terminal IN of the CMOS 19a illustrated in FIG. 2. The dashed line in FIG. 9 indicates that the capacitance at a potential difference Vg of 1 V is 8.9 fF/μm at a frequency of 10 GHz. The capacitance of the capacitor Q₀ at a frequency of 10 GHz is about 2.9 times the capacitance of the capacitor Q₂.

The capacitor Q₂ has the characteristics indicated by the dashed line in FIG. 8 when the frequency of signals supplied to the logic circuit 19 is 1 MHz. The capacitors Q₀ and Q₂ may have substantially the same characteristics. Since the first n-type impurity diffusion region 23 is formed, a higher capacitance may be obtained as frequencies becomes higher.

As illustrated in FIG. 6, the peaks of the n-type impurity concentrations of the first and second n-type impurity diffusion regions 23 and 24 are located at different positions along the depth. For example, because the first n-type impurity diffusion region 23 is formed, the lower portion of the second p-type impurity diffusion region 24, which corresponds to the lower electrode of the capacitor Q₀, has a higher impurity concentration, and accordingly the high-concentration n-type impurity region is thicker. As a result, the lower electrode of the capacitor Q₀ has a lower lateral resistance. Thus, the structural difference between the capacitors Q₀ and Q₂, for example, the presence or absence of the first n-type impurity diffusion region 23, which has a higher n-type impurity concentration than the n-type silicon layer 22, may result in the difference illustrated in FIG. 9.

When the second n-type impurity diffusion region 24 is at a positive potential, fewer majority carriers, for example, electrons, may not easily accumulate below the upper electrode 7a. Thus, as illustrated in FIGS. 8 and 9, the capacitance is lower when the voltage Vg of the upper electrode 7a is negative with respect to the second n-type impurity diffusion region 24.

The semiconductor substrate used may be the silicon substrate 1 or an SOI substrate. The silicon substrate 1 may be either p-type or n-type.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising a capacitor, the capacitor includes:
a first semiconductor region of a first conductivity type;
a second semiconductor region of the first conductivity type disposed on the first semiconductor region, the second semiconductor region having a higher first-conductivity-type impurity concentration than the first semiconductor region;
a third semiconductor region of the first conductivity type disposed on the second semiconductor region, the third semiconductor region including a contact region and having a higher first-conductivity-type impurity concentration than the second semiconductor region;
a dielectric film disposed on the third semiconductor region; and
an upper electrode disposed on the dielectric film beside the contact region.

2. The semiconductor device according to claim 1, wherein
the third semiconductor region has a first peak in a depth direction; and
the second semiconductor region has a second peak lower than the first peak in a depth direction.

3. The semiconductor device according to claim 1, wherein the upper electrode includes a first-conductivity-type semiconductor material having a higher first-conductivity-type impurity concentration than the third semiconductor region.

4. The semiconductor device according to claim 1, further comprising,
a pair of power supply lines, one of the power supply lines electrically connected to the upper electrode, the other power supply line electrically connected to the contact region of the third semiconductor region.

5. The semiconductor device according to claim 4, wherein
the third semiconductor region is an n-type semiconductor region; and
a voltage of the one of the power supply lines is higher than a voltage of the other power supply line.

6. The semiconductor device according to claim 4, wherein
the third semiconductor region is a p-type semiconductor region; and
a voltage of the one of the power supply lines is lower than a voltage of the other power supply line.

7. The semiconductor device according to claim 1, further comprising,
a first-conductivity-type well, disposed in the first semiconductor region, on which a metal-oxide-semiconductor transistor of a second conductivity type is formed,
the first-conductivity-type well and the first semiconductor region having the same first-conductivity-type impurity concentration or a difference in first-conductivity-type impurity concentration within one order of magnitude.

8. The semiconductor device according to claim 1, wherein the first semiconductor region is a layer epitaxially grown on a semiconductor substrate of the first conductivity type or a second conductivity type.

9. The semiconductor device according to claim 1, wherein
the second semiconductor region has a first-conductivity-type impurity concentration of from 5×10¹⁸ to 5×10¹⁹ cm⁻³; and
the third semiconductor region has a first-conductivity-type impurity concentration of from 1×10¹⁹ to 5×10²⁰ cm⁻³.

10. A method for manufacturing a semiconductor device, comprising:
forming a first semiconductor region of a first conductivity type on a semiconductor substrate;
forming a second semiconductor region of the first conductivity type on the first semiconductor region, the second semiconductor region having a higher first-conductivity-type impurity concentration than the first semiconductor region;
forming a third semiconductor region of the first conductivity type on the second semiconductor region, the third semiconductor region having a higher first-conductivity-type impurity concentration than the second semiconductor region;
forming a dielectric film on the third semiconductor region; and
forming an upper electrode on the dielectric film.

11. The method for manufacturing a semiconductor device according to claim 10, further comprising:
forming an insulating film on the upper electrode; and
forming a plug in the insulating film beside the dielectric film.

12. The method for manufacturing a semiconductor device according to claim 11, wherein the third semiconductor region includes a contact region for the plug.
